(19) United States
(12) Patent Application Publication
(10) Pub. No.: US 2026/0040535 A1
(43) Pub. Date: Feb. 5, 2026

(54) WORDLINE CONTACT ISOLATION STRUCTURE AND METHOD

(71) Applicant: Micron Technology, Inc., Boise, ID (US)

(72) Inventors: Collin Howder, Boise, ID (US); Andrew L. Li, Boise, ID (US); Jordan D. Greenlee, Boise, ID (US)

(21) Appl. No.: 19/269,560

(22) Filed: Jul. 15, 2025

Related U.S. Application Data
(60) Provisional application No. 63/677,146, filed on Jul. 30, 2024.

(51) Int. Cl. H10B 12/00; H01L 21/02; H01L 21/311; H01L 21/768; H01L 23/522; H01L 23/528

(52) U.S. Cl. CPC H10B 12/488; H01L 21/02164; H01L 21/31105; H01L 21/76877; H01L 23/5226; H01L 23/5283

(57) ABSTRACT

Devices and methods are disclosed, including transistors, semiconductor devices and systems. Example semiconductor devices and methods include interconnect structures with lateral isolation structures around a vertical conductor. Devices and methods are shown where the isolation structures are located with a staircase configuration in a memory device with an array of vertical memory strings.

### PRIORITY APPLICATION

This application claims the benefit of priority to U.S. Provisional Application Ser. No. 63/677,146, filed Jul. 30, 2024, which is incorporated herein by reference in its entirety.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to interconnect structures in memory devices, such as vertical NAND devices and manufacture.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2A illustrates a stage of manufacture of a memory device in accordance with some example embodiments.

FIG. 2B illustrates another stage of manufacture of a memory device in accordance with some example embodiments.

FIG. 2C illustrates another stage of manufacture of a memory device in accordance with some example embodiments.

FIG. 2D illustrates another stage of manufacture of a memory device in accordance with some example embodiments.

FIG. 2E illustrates another stage of manufacture of a memory device in accordance with some example embodiments.

FIG. 2F illustrates another stage of manufacture of a memory device in accordance with some example embodiments.

FIG. 2G illustrates another stage of manufacture of a memory device in accordance with some example embodiments.

FIG. 2H illustrates another stage of manufacture of a memory device in accordance with some example embodiments.

FIG. 3A illustrates selected isolation components of a memory device in accordance with some example embodiments.

FIG. 3B illustrates selected isolation components of a memory device in accordance with some example embodiments.

FIG. 4A illustrates selected isolation components of a memory device in accordance with some example embodiments.

FIG. 4B illustrates selected isolation components of a memory device in accordance with some example embodiments.

FIG. 5 illustrates an example method flow diagram in accordance with other example embodiments.

FIG. 6 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

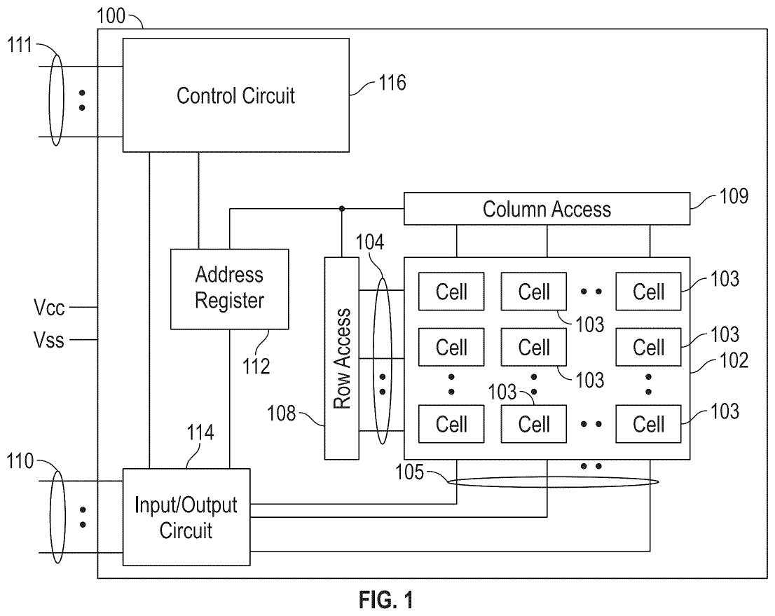

FIG. 1 shows a block diagram of an apparatus in the form of a memory device 100, according to an embodiment of the invention. Memory device 100 can include a memory array 102 having memory cells 103 that can be arranged in rows and columns along with lines (e.g., access lines) 104 and lines (e.g., data lines) 105. Memory device 100 can use lines 104 to access memory cells 103 and lines 105 to exchange information with memory cells 103.

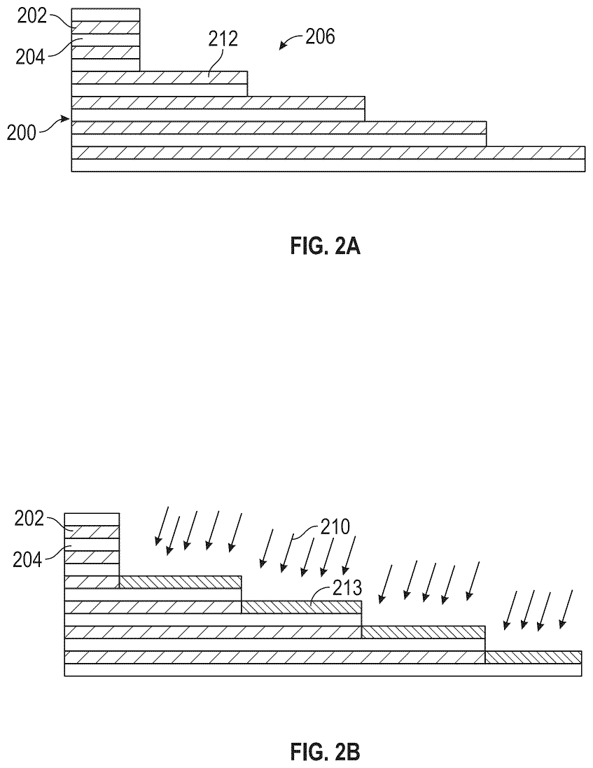

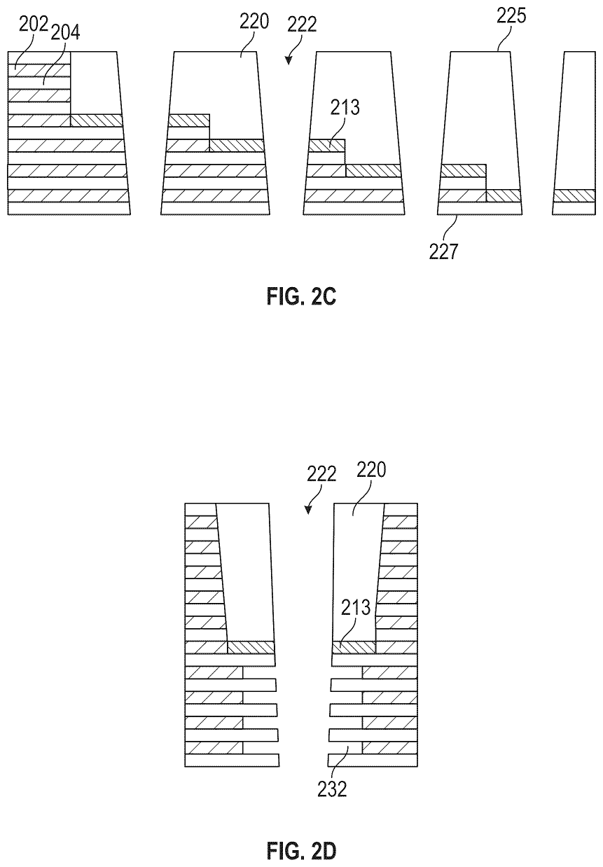

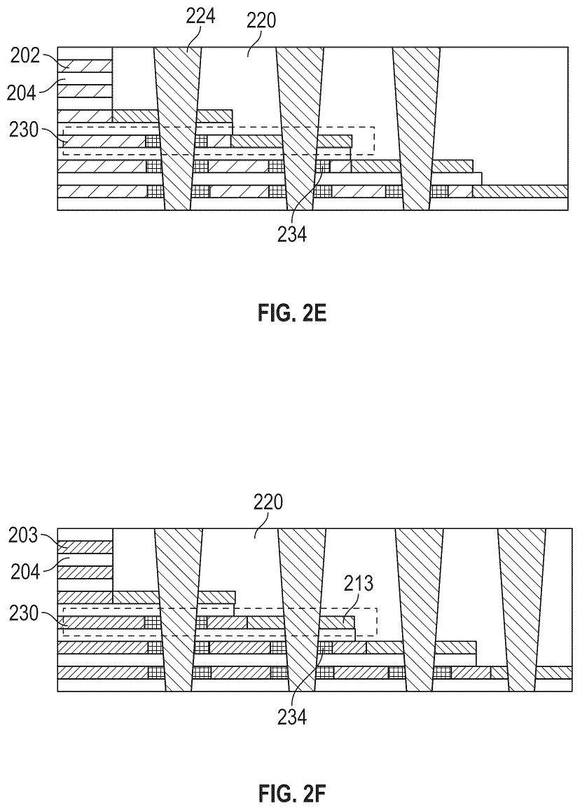

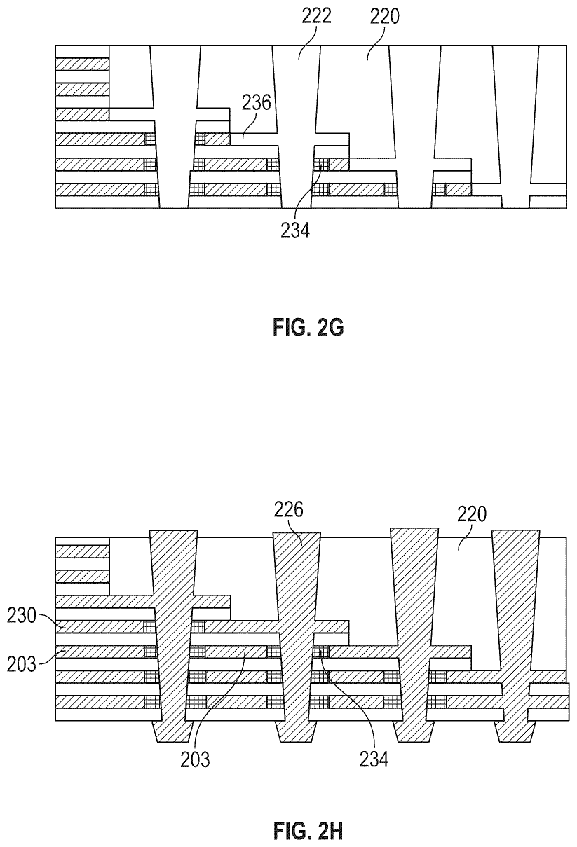

Memory cells 103 and other circuits 114, 116, etc. may include transistors and utilize methods as described in more detail in FIGS. 2A-4. In one example, memory arrays 102 include RAM storage, and peripheral circuits such as circuits 114, 116, 108, 109, etc. may include transistors as described in more detail in FIGS. 2A-4. In one example, memory arrays 102 include NAND storage.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that has the ability to store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash or a NOR flash memory device, or another kind of memory device, such as a variable resistance memory device (e.g., a phase change or resistive RAM device).

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100.

One of ordinary skill in the art will recognize that memory device 100 may include other elements, several of which are not shown in FIG. 1, so as not to obscure the example embodiments described herein.

FIGS. 2A-2G show selected stages of manufacture of an example memory device. In FIG. 2A, a stack 200 of alternating dielectric layers 204 and placeholder layers 202 is shown. In one example, the dielectric layers 204 include silicon oxide and the placeholder layers 202 include nitride. The placeholder layers 202 will be replaced by conductor layers in a later stage of manufacture as discussed in more detail below.

A staircase structure 206 including a number of staircase treads 212 is shown in the stage of manufacture of FIG. 2A. In one example, the staircase 206 is used to construct an interconnection configuration to electrically access a number of memory cells that are formed in the stack 200. The number of memory cells are not shown in FIG. 2A, but are located adjacent to the staircase 206, for example, to the left of the configuration shown in FIG. 2A. In one example, the staircase 206 is included in the memory device 100 shown in FIG. 1.

In FIG. 2B, an implant operation shown by arrows 210 implants a dopant into the treads 212 to form etch selective treads 213. In one example, the implant includes carbon atoms, to form carbonitride etch selective treads 213 although the invention is not so limited. Etch selective treads 213 are used to form different electrical conductor structures and electrical isolation structures as discussed in more detail below.

In FIG. 2C, a dielectric fill 220 is formed over the staircase 206. The dielectric fill 220 forms a level top surface 225 of the stack 200. The etch selective treads 213 of the staircase 206 are encased within the stack 200 and covered by the dielectric fill 220. In FIG. 2C, a vertical passage 222 is formed between a top surface 225 and a bottom surface 227 of the stack 200.

In FIG. 2D, an etch operation is performed within the vertical passage 222. The etch selective treads 213 are unaffected or minimally affected by the etch operation of FIG. 2D because of the etch selectivity. Exposed portions of the placeholder layers 202 are etched, and form lateral isolation cavities 232.

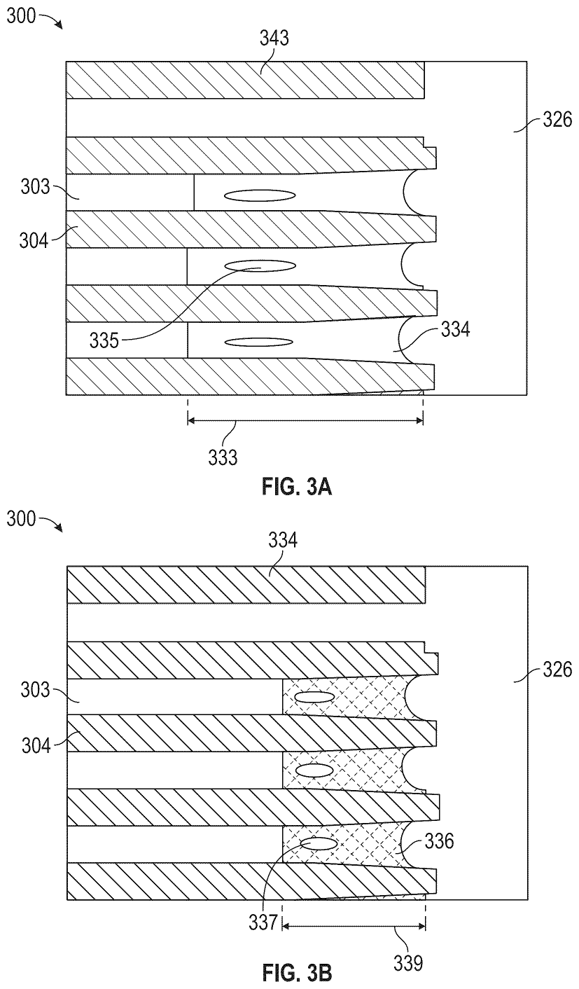

In FIG. 2E, the vertical passage 222 and the lateral isolation cavities 232 are filled with a dielectric material 224. The portion of the dielectric material 224 that fills the lateral isolation cavities 232 forms lateral isolation structures 234. As described in more detail below, the lateral isolation structures 234 provide electrical isolation between a vertical conductor and one or more conductor layers that are formed from the placeholder layers 202. Additional examples of lateral isolation structures are discussed in more detail in FIGS. 3A and 3B.

A selected conductor layer 230 is further illustrated in FIG. 2E. As described in more detail below, a vertical conductor (discussed in more detail below) is formed in electrical contact with the selected conductor layer 230, but is electrically isolated from other conductor layers by the lateral isolation structures 234.

In FIG. 2F, a replacement gate operation is performed. In the replacement gate operation, the placeholder layers 202 are removed, and a final conductor layers 203 are formed in the space left behind by the removed placeholder layers 202. By performing the replacement gate operation after a number of earlier manufacturing processes, a number of device structures are more easily formed using the early stage placeholder layers 202, and the final conductor layers 203 are only formed later. In some examples, the final conductor layers 203 are more difficult to etch, or otherwise configure. Therefore, forming them in a later stage manufacturing process at the replacement gate stage makes manufacture of devices with high electrical conductivity easier and less expensive.

In one example, the final conductor layers 203 include tungsten, although the invention is not so limited. As illustrated in FIG. 2F, the etch selective treads 213 are still in place at this stage of manufacture.

In FIG. 2G, the dielectric material 224 in the vertical passage 222 is removed and another etch operation is performed. In the etch operation, the etch selective treads 213 are selectively removed. The etchant chosen to remove the etch selective treads 213 reacts substantially only with the etch selective treads 213, and other exposed structures are substantially unaffected. For example, the lateral isolation structures 234 remain behind. After removal of the etch selective treads 213, lateral connection cavities 236 are formed.

In FIG. 2H, a vertical conductor 226 is filled into the vertical passage 222 and into the lateral connection cavities 236 from FIG. 2G. In the resulting structure of FIG. 2H, the selected conductor layer 230 is electrically coupled to the vertical conductor 226. At the same time, the lateral isolation structures 234 separate the vertical conductor 226 from other final conductor layers 203.

In operation, it is important that the vertical conductor 226 is electrically isolated from final conductor layers 203 that are not selected. Improving the dielectric properties of the lateral isolation structures 234 improves the effectiveness of the electrical isolation.

FIGS. 3A and 3B illustrate a closer view of another example of a portion of a stack 300. The stack 300 includes alternating dielectric layers 304 and conductor layers 303. In one example, the conductor layers 303 are shown after a replacement gate operation such as shown in FIG. 2F. FIG. 3A further shows lateral isolation structures 334, similar to lateral isolation structures 234 from FIG. 2H. In FIG. 3A, a portion of a vertical conductor 326 is shown, similar to vertical conductor 226 from FIG. 2H. The vertical conductor 326 is electrically coupled to selected conductor layer 343, and electrically isolated from other conductor layers 303 in the stack 300 by lateral isolation structures 334.

In the example of FIG. 3A, the lateral isolation structures 334 include a middle void 335. In some examples a middle void 335 is formed as dielectric material is deposited into lateral isolation cavities, such as lateral isolation cavities 232 from FIG. 2D. Deposition kinetics may close off the opening to the lateral isolation cavities before the middle void 335 is completely filled. Other example lateral isolation structures may not include a middle void.

The lateral isolation structures 334 are shown with a width 333. A number of design parameters are taken into account when designing a device and specifying the width 333. Factors such as an applied voltage, geometry of the lateral isolation structures 334, dielectric constant of the dielectric material that forms the lateral isolation structures 334, etc. are taken into account to select an appropriate width 333. Too shallow of a width 333 may result in unwanted electrical leakage or shorting between the vertical conductor 326 and conductor layers 303 separate by the lateral isolation structures 334. In one example, the lateral isolation structures 334 of FIG. 3A are formed from silicon oxide, and have a corresponding width 333 based in part on the dielectric constant of silicon oxide. In one example, a dielectric constant of the lateral isolation structures 334 is about 3.9. In one example, a dielectric constant of silicon oxide varies between 3.7 and 3.9.

In FIG. 3B, a similar stack 300 is shown, however, different lateral isolation structures 336 are shown. In one example, the lateral isolation structures 336 include a dielectric material having a lower dielectric constant than silicon oxide. Similar to the lateral isolation structures 334 of FIG. 3A, in one example the lateral isolation structures 336 include a middle void 337, although the invention is not so limited.

In one example, the lateral isolation structures 336 include a dielectric material having a lower dielectric constant than 4.0. In one example, the lateral isolation structures 336 include an oxide material having a lower dielectric constant than 4.0. In one example, the lateral isolation structures 336 include a modified silicon oxide. In one example, the modified silicon oxide includes a doped silicon oxide. Examples of dopants include, but are not limited to, carbon, fluorine, or other dopants similarly situated on the periodic table.

In one example, the modified silicon oxide includes a porous silicon oxide. As noted above, in selected examples, a middle void 337 is included. A void provides a lower dielectric constant that silicon oxide. The presence of one or more voids provides a composite dielectric constant based on an amount of voids and a void distribution. In one example, the silicon oxide includes a number of smaller void in addition to a middle void 337. In one example, a more uniform distribution of voids provides a more consistent composite dielectric constant for the lateral isolation structures 336.

In one example, the lateral isolation structures 336 include a nitride material having a lower dielectric constant than 4.0. In one example, the lateral isolation structures 336 include a modified silicon nitride. In one example, the modified silicon nitride includes a doped silicon nitride. In one example, the modified silicon nitride includes a porous silicon nitride.

In one example, the lateral isolation structures 336 formed with a material having a dielectric constant lower than silicon oxide provide a smaller width 339 than the width 333 of the lateral isolation structures 334 of FIG. 3A. For example, a porous silicon oxide lateral isolation structure is approximately one half of the width of unmodified silicon oxide, with the same dielectric effect. By shortening the width 339, devices can be formed in a more compact space, which can lead to improved memory density and better electrical performance. Conversely, if a width 339 is kept the same, but the lateral isolation structures utilize lower dielectric constant materials, the electric performance improves.

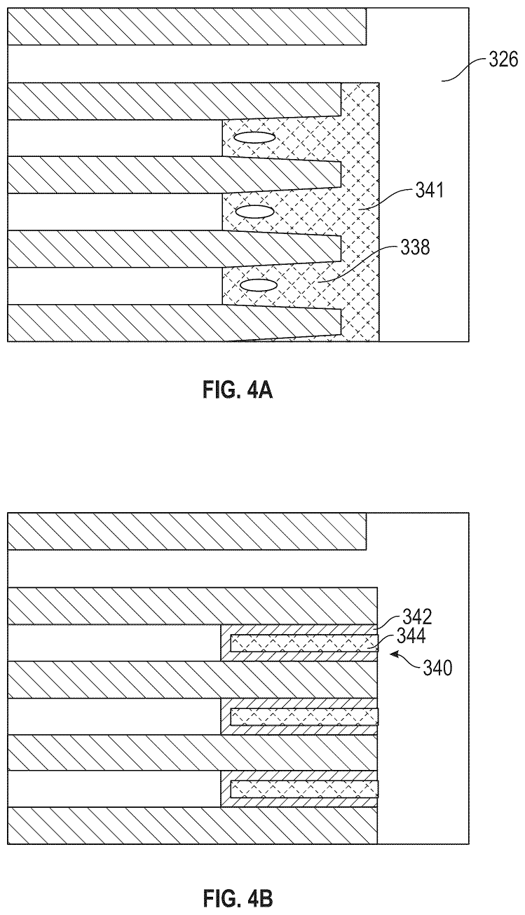

FIGS. 4A and 4B illustrate additional examples of lateral isolation structures that are improved over silicon oxide. In FIG. 4A, lateral isolation structures 338 are shown, however dielectric material 341 further covers sidewalls of the vertical conductor 326 between at least two lateral isolation structures 338. The example of FIG. 4A may be easier to manufacture, as it does not require tight controls on etching the dielectric material in the lateral isolation structures 338. In one example a buffered oxide etch is used to control etching a modified silicon oxide material. A buffered oxide etch may moderate a faster etch rate caused by dopants or pores in the modified dielectric material.

FIG. 4B shows lateral isolation structures 340 having multiple dielectric materials in different layers. A first layer 342 is deposited, then a second layer 344 fills in the remaining cavity in the first layer 342. Using multiple dielectric materials in layers provides another useful manufacturing dimension to control electrical/dielectric properties of the lateral isolation structures 340. The first layer 342 may include a very low dielectric constant, but may be difficult or slow to deposit. The second layer may then be used to finish manufacture of the lateral isolation structures 340. Although two layers 342, 344 are shown, the invention is not so limited. More than two layers are also within the scope of the invention.

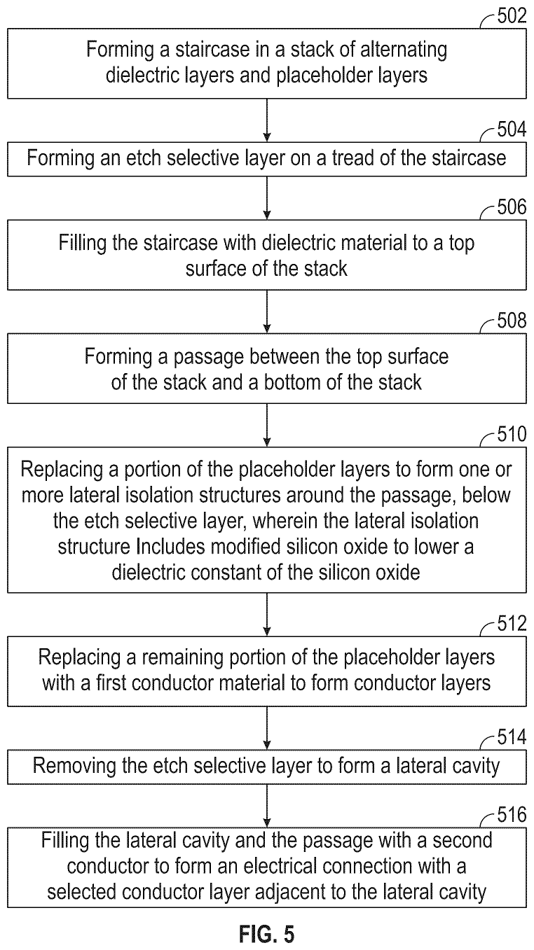

FIG. 5 shows a flow diagram of an example method of manufacture. In operation 502, a staircase is formed in a stack of alternating dielectric layers and placeholder layers. In operation 504, an etch selective layer is formed on a tread of the staircase. In operation 506, the staircase is filled with dielectric material to a top surface of the stack. In operation 508, a vertical passage is formed between the top surface of the stack and a bottom of the stack. In operation 510, a portion of the placeholder layers are replaced to form one or more lateral isolation structures around the vertical passage, below the etch selective layer, wherein the one or more lateral isolation structures include modified silicon oxide to lower a dielectric constant compared to silicon oxide. In operation 512, a remaining portion of the placeholder layers are replaced with a first conductor material to form conductor layers. In operation 514, the etch selective layer is removed to form a lateral cavity, and in operation 516, the lateral cavity and the vertical passage are filled with a second conductor to form an electrical connection with a selected conductor layer adjacent to the lateral cavity.

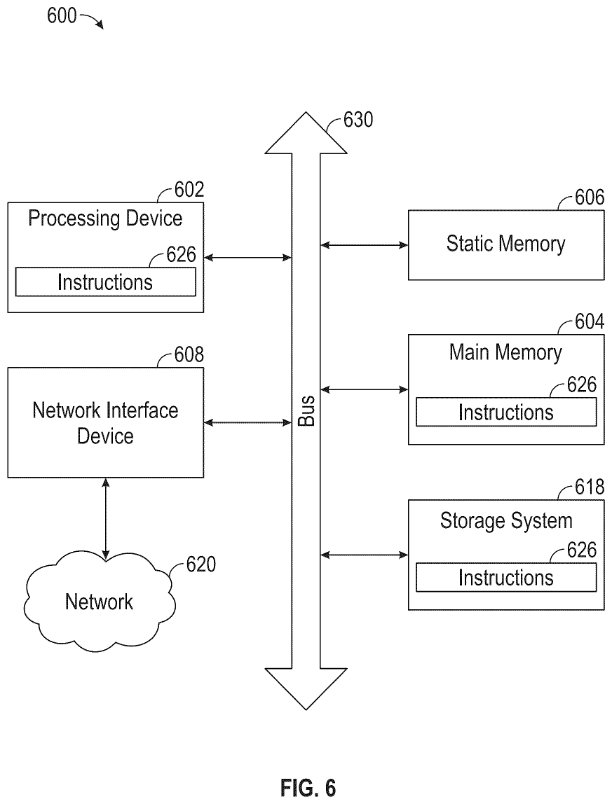

FIG. 6 illustrates a block diagram of an example machine (e.g., a host system) 600 which may include one or interconnect structures, vertical conductors, isolation structures, memory devices and/or memory systems as described above. As discussed above, machine 600 may benefit from enhanced memory performance from use of one or more of the described structures and/or memory systems, facilitating improved performance of machine 600 (as for many such machines or systems, efficient reading and writing of memory can facilitate improved performance of a processor or other components that machine, as described further below.

In alternative embodiments, the machine 600 may operate as a standalone device or may be connected (e.g., networked) to other machines. In a networked deployment, the machine 600 may operate in the capacity of a server machine, a client machine, or both in server-client network environments. In an example, the machine 600 may act as a peer machine in peer-to-peer (P2P) (or other distributed) network environment. The machine 600 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (Saas), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 600 may include a processing device 602 (e.g., a hardware processor, a central processing unit (CPU), a graphics processing unit (GPU), a hardware processor core, or any combination thereof, etc.), a main memory 604 (e.g., read-only memory (ROM), dynamic random-access memory (DRAM) such as synchronous DRAM (SDRAM) or Rambus DRAM (RDRAM), etc.), a static memory 606 (e.g., static random-access memory (SRAM), etc.), and a storage system 618, some or all of which may communicate with each other via a communication interface (e.g., a bus) 630. In one example, the main memory 604 includes one or more memory devices as described in examples above.

The processing device 602 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 602 can also be one or more special-purpose processing devices such as an application specific integrated circuit (ASIC), a field programmable gate array (FPGA), a digital signal processor (DSP), network processor, or the like. The processing device 602 can be configured to execute instructions 626 for performing the operations and steps discussed herein. The computer system 600 can further include a network interface device 608 to communicate over a network 620.

The storage system 618 can include a machine-readable storage medium (also known as a computer-readable medium) on which is stored one or more sets of instructions 626 or software embodying any one or more of the methodologies or functions described herein. The instructions 626 can also reside, completely or at least partially, within the main memory 604 or within the processing device 602 during execution thereof by the computer system 600, the main memory 604 and the processing device 602 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 600 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 600 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 626 (e.g., software, programs, an operating system (OS), etc.) or other data are stored on the storage system 618 can be accessed by the main memory 604 for use by the processing device 602. The main memory 604 (e.g., DRAM) is typically fast, but volatile, and thus a different type of storage than the storage system 618 (e.g., an SSD), which is suitable for long-term storage, including while in an “off” condition. The instructions 626 or data in use by a user or the machine 600 are typically loaded in the main memory 604 for use by the processing device 602. When the main memory 604 is full, virtual space from the storage system 618 can be allocated to supplement the main memory 604; however, because the storage system 618 device is typically slower than the main memory 604, and write speeds are typically at least twice as slow as read speeds, use of virtual memory can greatly reduce user experience due to storage system latency (in contrast to the main memory 604, e.g., DRAM). Further, use of the storage system 618 for virtual memory can greatly reduce the usable lifespan of the storage system 618.

The instructions 626 may further be transmitted or received over a network 620 using a transmission medium via the network interface device 608 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®), IEEE 802.15.4 family of standards, peer-to-peer (P2P) networks, among others. In an example, the network interface device 608 may include one or more physical jacks (e.g., Ethernet, coaxial, or phone jacks) or one or more antennas to connect to the network 620. In an example, the network interface device 608 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 600, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

To better illustrate the method and apparatuses disclosed herein, a non-limiting list of embodiments is provided here:

### Example 1

A memory device, comprising; a stack of alternating dielectric layers and conductor layers; a number of memory cells formed within the stack of alternating dielectric layers and conductor layers; a vertical conductor passing from a top level of the stack to at least a selected conductor layer from the stack; a lateral connection between a location along the vertical conductor and the selected conductor layer from the stack; and a lateral isolation structure around the vertical conductor adjacent to at least one other conductor layer from the stack, wherein the lateral isolation structure includes a dielectric material having a lower dielectric constant than 4.0.

### Example 2

The memory device of example 1, wherein the lateral isolation structure includes modified silicon oxide.

### Example 3

The memory device of example 1, wherein the lateral isolation structure includes modified silicon nitride.

### Example 4

The memory device of example 1, wherein the lateral isolation structure includes multiple dielectric materials in different layers.

### Example 5

The memory device of example 1, wherein the lateral isolation structure includes the dielectric material extending into multiple lateral cavities around the vertical conductor.

### Example 6

The memory device of example 5, wherein the lateral isolation structure includes the dielectric material further covering sidewalls of the vertical conductor between at least two of the multiple lateral cavities.

### Example 7

The memory device of example 1, wherein the vertical conductor extends between the top level of the stack and a bottom level of the stack.

### Example 8

The memory device of example 7, wherein the lateral isolation structure is located below the selected conductor layer from the stack.

### Example 9

A memory device, comprising; a stack of alternating dielectric layers and conductor layers; a number of memory cells formed within the stack of alternating dielectric layers and conductor layers; vertical conductor passing from a top level of the stack to at least a selected conductor layer from the stack; a lateral connection between a location along the vertical conductor and the selected conductor layer from the stack; and a lateral isolation structure around the vertical conductor adjacent to at least one other conductor layer from the stack, wherein the lateral isolation structure includes modified silicon oxide to provide a lower dielectric constant than silicon oxide.

### Example 10

The memory device of example 9, wherein the modified silicon oxide includes doped silicon oxide.

### Example 11

The memory device of example 10, wherein the doped silicon oxide includes carbon doped silicon oxide.

### Example 12

The memory device of example 10, wherein the doped silicon oxide includes fluorine doped silicon oxide.

### Example 13

The memory device of example 9, wherein the modified silicon oxide includes porous silicon oxide.

### Example 14

The memory device of example 9, wherein the vertical conductor extends between the top level of the stack and a bottom level of the stack.

### Example 15

The memory device of example 9, wherein the lateral isolation structure includes multiple dielectric materials in different layers.

### Example 16

A method of forming a memory device, comprising; forming a staircase in a stack of alternating dielectric layers and placeholder layers; forming an etch selective layer on a tread of the staircase; filling the staircase with dielectric material to a top surface of the stack; forming a vertical passage between the top surface of the stack and a bottom of the stack; replacing a portion of the placeholder layers to form one or more lateral isolation structures around the vertical passage, below the etch selective layer, wherein the one or more lateral isolation structures include modified silicon oxide to lower a dielectric constant compared to silicon oxide; replacing a remaining portion of the placeholder layers with a first conductor material to form conductor layers; removing the etch selective layer to form a lateral cavity; and filling the lateral cavity and the vertical passage with a second conductor to form an electrical connection with a selected conductor layer adjacent to the lateral cavity.

### Example 17

The method of example 16, wherein replacing a portion of the placeholder layers to form one or more lateral isolation structures includes; etching the portion of the placeholder layers to form one or more lateral cavities; filling the one or more lateral cavities and at least a portion of the vertical passage with the modified silicon oxide; and etching the modified silicon oxide to remove at least some of the modified silicon oxide in the vertical passage.

### Example 18

The method of example 17, wherein etching the modified silicon oxide includes a buffered oxide etch.

### Example 19

The method of example 17, wherein etching the modified silicon oxide includes leaving modified silicon oxide in the one or more lateral cavities and leaving a layer of modified silicon oxide on sidewalls of the vertical passage.

### Example 20

The method of example 16, wherein forming the etch selective layer includes implanting carbon in an end portion of a selected placeholder layer.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A memory device, comprising;
a stack of alternating dielectric layers and conductor layers;
a number of memory cells formed within the stack of alternating dielectric layers and conductor layers;
a vertical conductor passing from a top level of the stack to at least a selected conductor layer from the stack;
a lateral connection between a location along the vertical conductor and the selected conductor layer from the stack; and
a lateral isolation structure around the vertical conductor adjacent to at least one other conductor layer from the stack, wherein the lateral isolation structure includes a dielectric material having a lower dielectric constant than 4.0.

2. The memory device of claim 1, wherein the lateral isolation structure includes modified silicon oxide.

3. The memory device of claim 1, wherein the lateral isolation structure includes modified silicon nitride.

4. The memory device of claim 1, wherein the lateral isolation structure includes multiple dielectric materials in different layers.

5. The memory device of claim 1, wherein the lateral isolation structure includes the dielectric material extending into multiple lateral cavities around the vertical conductor.

6. The memory device of claim 5, wherein the lateral isolation structure includes the dielectric material further covering sidewalls of the vertical conductor between at least two of the multiple lateral cavities.

7. The memory device of claim 1, wherein the vertical conductor extends between the top level of the stack and a bottom level of the stack.

8. The memory device of claim 7, wherein the lateral isolation structure is located below the selected conductor layer from the stack.

9. A memory device, comprising;
a stack of alternating dielectric layers and conductor layers;
a number of memory cells formed within the stack of alternating dielectric layers and conductor layers;
vertical conductor passing from a top level of the stack to at least a selected conductor layer from the stack;
a lateral connection between a location along the vertical conductor and the selected conductor layer from the stack; and
a lateral isolation structure around the vertical conductor adjacent to at least one other conductor layer from the stack, wherein the lateral isolation structure includes modified silicon oxide to provide a lower dielectric constant than silicon oxide.

10. The memory device of claim 9, wherein the modified silicon oxide includes doped silicon oxide.

11. The memory device of claim 10, wherein the doped silicon oxide includes carbon doped silicon oxide.

12. The memory device of claim 10, wherein the doped silicon oxide includes fluorine doped silicon oxide.

13. The memory device of claim 9, wherein the modified silicon oxide includes porous silicon oxide.

14. The memory device of claim 9, wherein the vertical conductor extends between the top level of the stack and a bottom level of the stack.

15. The memory device of claim 9, wherein the lateral isolation structure includes multiple dielectric materials in different layers.

16. A method of forming a memory device, comprising;
forming a staircase in a stack of alternating dielectric layers and placeholder layers;
forming an etch selective layer on a tread of the staircase;
filling the staircase with dielectric material to a top surface of the stack;
forming a vertical passage between the top surface of the stack and a bottom of the stack;
replacing a portion of the placeholder layers to form one or more lateral isolation structures around the vertical passage, below the etch selective layer, wherein the one or more lateral isolation structures include modified silicon oxide to lower a dielectric constant compared to silicon oxide;
replacing a remaining portion of the placeholder layers with a first conductor material to form conductor layers;
removing the etch selective layer to form a lateral cavity; and
filling the lateral cavity and the vertical passage with a second conductor to form an electrical connection with a selected conductor layer adjacent to the lateral cavity.

17. The method of claim 16, wherein replacing a portion of the placeholder layers to form one or more lateral isolation structures includes;
etching the portion of the placeholder layers to form one or more lateral cavities;
filling the one or more lateral cavities and at least a portion of the vertical passage with the modified silicon oxide; and
etching the modified silicon oxide to remove at least some of the modified silicon oxide in the vertical passage.

18. The method of claim 17, wherein etching the modified silicon oxide includes a buffered oxide etch.

19. The method of claim 17, wherein etching the modified silicon oxide includes leaving modified silicon oxide in the one or more lateral cavities and leaving a layer of modified silicon oxide on sidewalls of the vertical passage.

20. The method of claim 16, wherein forming the etch selective layer includes implanting carbon in an end portion of a selected placeholder layer.
